(19) United States
(12) Patent Application Publication
(10) Pub. No.: US 2016/0276219 A1
(43) Pub. Date: Sep. 22, 2016

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Makoto WADA, Yokkaichi Mie (JP); Yuichi YAMAZAKI, Inagi Tokyo (JP); Hisao MIYAZAKI, Yokohama Kanagawa (JP); Akihiro KAJITA, Yokkaichi Mie (JP); Tatsuro SAITO, Yokkaichi Mie (JP); Atsunobu ISOBAYASHI, Yokkaichi Mie (JP); Taishi ISHIKURA, Kuwana Mie (JP); Masayuki KATAGIRI, Kawasaki Kanagawa (JP); Tadashi SAKAI, Yokohama Kanagawa (JP)

(73) Assignee: KABUSHIKI KAISHA TOSHIBA, Tokyo (JP)

(21) Appl. No.: 14/841,333

(22) Filed: Aug. 31, 2015

(30) Foreign Application Priority Data
Mar. 16, 2015 (JP) 2015-052403

(51) Int. Cl. H01L 21/768; H01L 23/532; H01L 23/528

(52) U.S. Cl. CPC H01L 21/76886; H01L 21/76834; H01L 21/76876; H01L 21/76879; H01L 23/528; H01L 23/53276

(57) ABSTRACT

According to one embodiment, a method of manufacturing a semiconductor device, the method includes forming a graphene film on a catalytic layer, removing a part of the graphene film to form an exposed side surface of the graphene film, introducing dopant into the graphene film from the exposed side surface, and forming a graphene interconnect by patterning the graphene film into which the dopant is introduced.

### CROSS-REFERENCE TO RELATED APPLICATIONS

This application is based upon and claims the benefit of priority from Japanese Patent Application No. 2015-052403, filed Mar. 16, 2015, the entire contents of which are incorporated herein by reference.

### FIELD

Embodiments described herein relate generally to a semiconductor device and a method of manufacturing the same.

### BACKGROUND

As semiconductor devices are miniaturized, interconnects are similarly miniaturized. When the width or height of an interconnect becomes closer to the mean free path of electrons, an increase in the resistance rate caused by the interface inelastic scattering of electrons becomes a serious problem.

In order to solve the above-described problem, interconnects using graphene have been proposed. In the case of using an interconnect made of graphene, it is possible to further reduce resistance by introducing dopant such as a halogen compound into graphene.

However, there is a problem that the dopant the graphene interconnect is doped with is likely to escape from the end face of the graphene interconnect.

Therefore, there is demand for a structure and a method of manufacturing the same which do not allow dopant to escape from a graphene interconnect easily.

Further, a graphene film is generally formed on a layer of a catalytic metal such as cobalt or nickel. However, there is a problem that dopant such as a halogen compound corrodes or etches the catalytic metal.

Therefore, there is demand for a structure which can prevent an undesirable influence of dopant on a catalytic layer.

### BRIEF DESCRIPTION OF THE DRAWINGS

FIG. 1 is an exemplary sectional view of a part of the method of manufacturing a semiconductor device of a first embodiment.

FIG. 2 is an exemplary sectional view of another part of the method of manufacturing the semiconductor device of the first embodiment.

FIG. 3 is an exemplary sectional view of another part of the method of manufacturing the semiconductor device of the first embodiment.

FIG. 4 is an exemplary sectional view of another part of the method of manufacturing the semiconductor device of the first embodiment.

FIG. 5 is an exemplary sectional view of another part of the method of manufacturing the semiconductor device of the first embodiment.

FIG. 6 is an exemplary sectional view of another part of the method of manufacturing the semiconductor device of the first embodiment.

FIG. 7 is an exemplary sectional view of another part of the method of manufacturing the semiconductor device of the first embodiment.

FIG. 8 is an exemplary plan view of a part of the method of manufacturing the semiconductor device of the first embodiment.

FIG. 9 is an exemplary plan view of another part of the method of manufacturing the semiconductor device of the first embodiment.

FIG. 10 is an exemplary plan view of another part of the method of manufacturing the semiconductor device of the first embodiment.

FIG. 11 is an exemplary plan view of another part of the method of manufacturing the semiconductor device of the first embodiment.

FIG. 12 is an exemplary plan view of a part of the method of manufacturing a semiconductor device of a first modified example of the first embodiment.

FIG. 13 is an exemplary sectional view of a part of the method of manufacturing a semiconductor device of a second modified example of the first embodiment.

FIG. 14 is an exemplary sectional view of another part of the method of manufacturing the semiconductor device of the second modified example of the first embodiment.

FIG. 15 is an exemplary sectional view of a part of the manufacturing method of a semiconductor device of a second embodiment.

FIG. 16 is an exemplary sectional view of another part of the manufacturing method of the semiconductor device of the second embodiment.

FIG. 17 is an exemplary sectional view of another part of the manufacturing method of the semiconductor device of the second embodiment.

### DETAILED DESCRIPTION

In general, according to one embodiment, a method of manufacturing a semiconductor device, the method includes: forming a graphene film on a catalytic layer; removing a part of the graphene film to form an exposed side surface of the graphene film; introducing dopant into the graphene film from the exposed side surface; and forming a graphene interconnect by patterning the graphene film into which the dopant is introduced.

Embodiments will be described hereinafter with reference to the accompanying drawings.

### First Embodiment

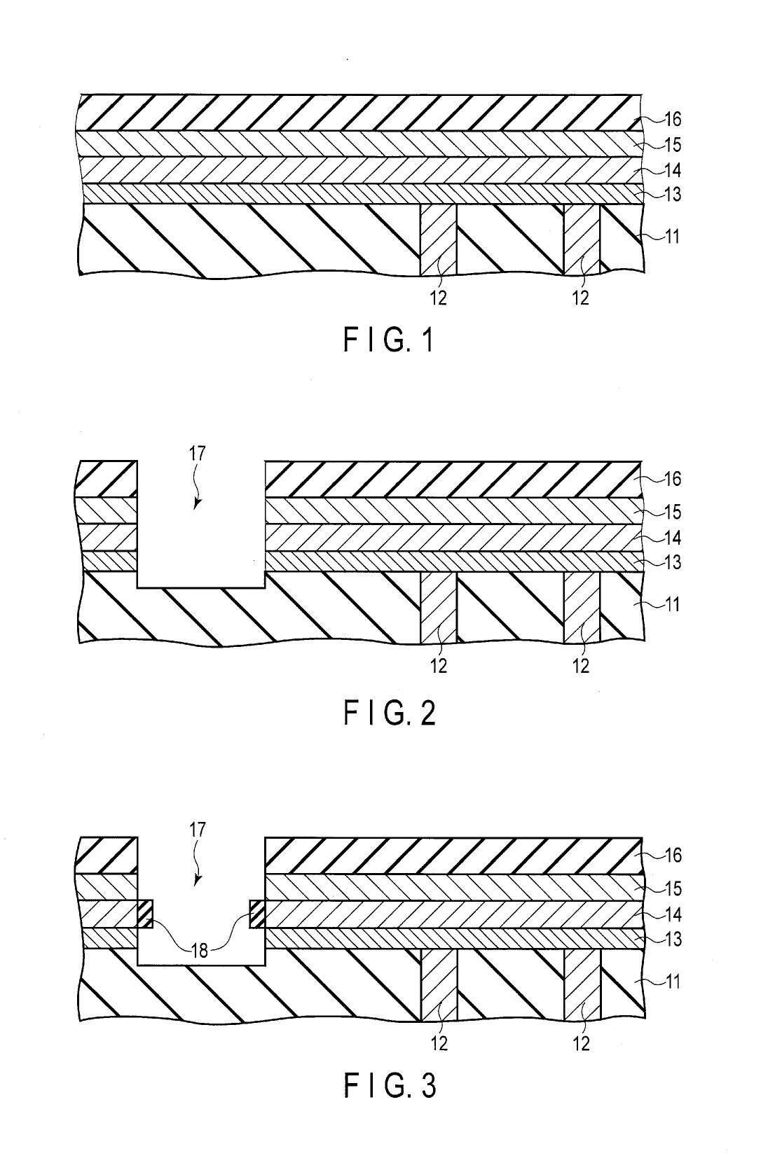

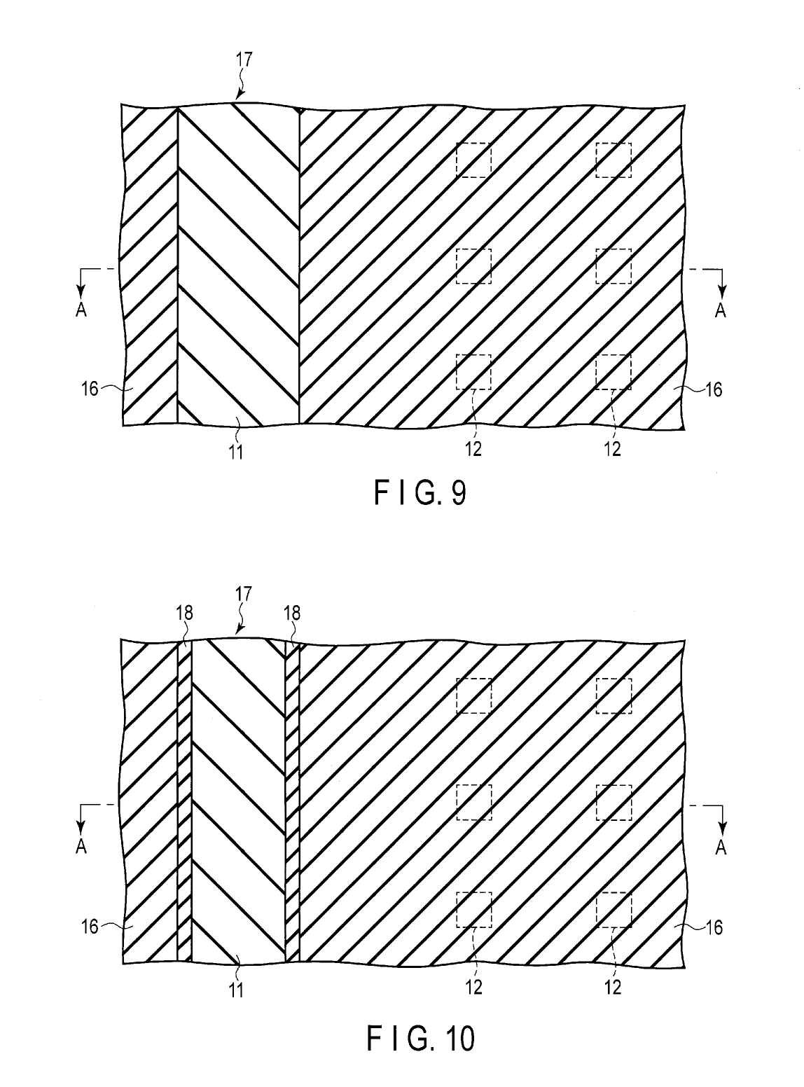

FIGS. 1 to 7 are exemplary sectional views of the method of manufacturing a semiconductor device of a first embodiment. FIGS. 8 to 11 are exemplary plan views of the method of manufacturing the semiconductor device of the first embodiment. Note that FIGS. 1, 2, 3 and 5 correspond respectively to the sections taken along line A-A of FIGS. 8, 9, 10 and 11.

First, as shown in FIGS. 1 and 8, an interlayer insulating film 11 and a contact 12 are formed on a semiconductor substrate (not shown). In the surface region of the semiconductor substrate, a MOS transistor or the like is formed. For the interlayer insulating film 11, a TEOS silicon oxide film is used. The contact 12 comprises a main metal film made of tungsten (W), copper (Cu), aluminum (Al) or the like. The contact 12 may further comprise a barrier metal film in addition to the main metal film. For the barrier metal film, tantalum (Ta), titanium (Ti), ruthenium (Ru), manganese (Mn) or cobalt (Co), or a metal nitride thereof is used.

Next, on the region in which the interlayer insulating film 11 and the contact 12 are formed, an underlying conductive layer 13 is formed by physical vapor deposition (PVD). The underlying conductive layer 13 is made of titanium (Ti), tantalum (Ta), ruthenium (Ru) or tungsten (W), or a metal nitride or a metal oxide thereof.

On the underlying conductive layer 13, a catalytic layer 14 is then formed by PVD. The catalytic layer 14 contains a metal element selected from cobalt (Co), nickel (Ni), iron (Fe), ruthenium (Ru) and copper (Cu). More specifically, the catalytic layer 14 is formed of a cobalt layer, a nickel layer, an iron layer, a ruthenium layer or a copper layer. The catalytic layer 14 functions as a catalyst for forming a graphene film. In order to form an even graphene film, the catalytic layer 14 is preferably a continuous film having a thickness of 0.5 nm or more.

On the catalytic layer 14, a graphene film 15 is then formed by chemical vapor deposition (CVD). More specifically, the graphene film 15 is formed by plasma CVD or thermal CVD at a temperature of 450° C. or more. As the source gas for CVD, methanol, ethanol, acetylene or the like is used. For the graphene film 15, multilayer graphene formed of a plurality of stacked graphite layers is used.

On the graphene film 15, a hard mask 16 is then formed. The hard mask 16 is made of a silicon oxide film or a silicon nitride film.

Next, as shown in FIGS. 2 and 9, the stacked film of the underlying conductive layer 13, the catalytic layer 14, the graphene film 15 and the hard mask film 16 is partly removed by lithography or reactive ion etching (RIE). In this way, a trench 17 is formed. That is, a step constituting the side surface of the trench 17 is formed. On the side surface of the trench (step) 17, the underlying conductive layer 13, the catalytic layer 14 and the graphene film 15 are exposed. The trench (step) 17 is used for introducing dopant into the graphene film 15 in a process which will be described later. For this reason, the trench (step) 17 is formed in a region of the graphene film 15 not used as an interconnect.

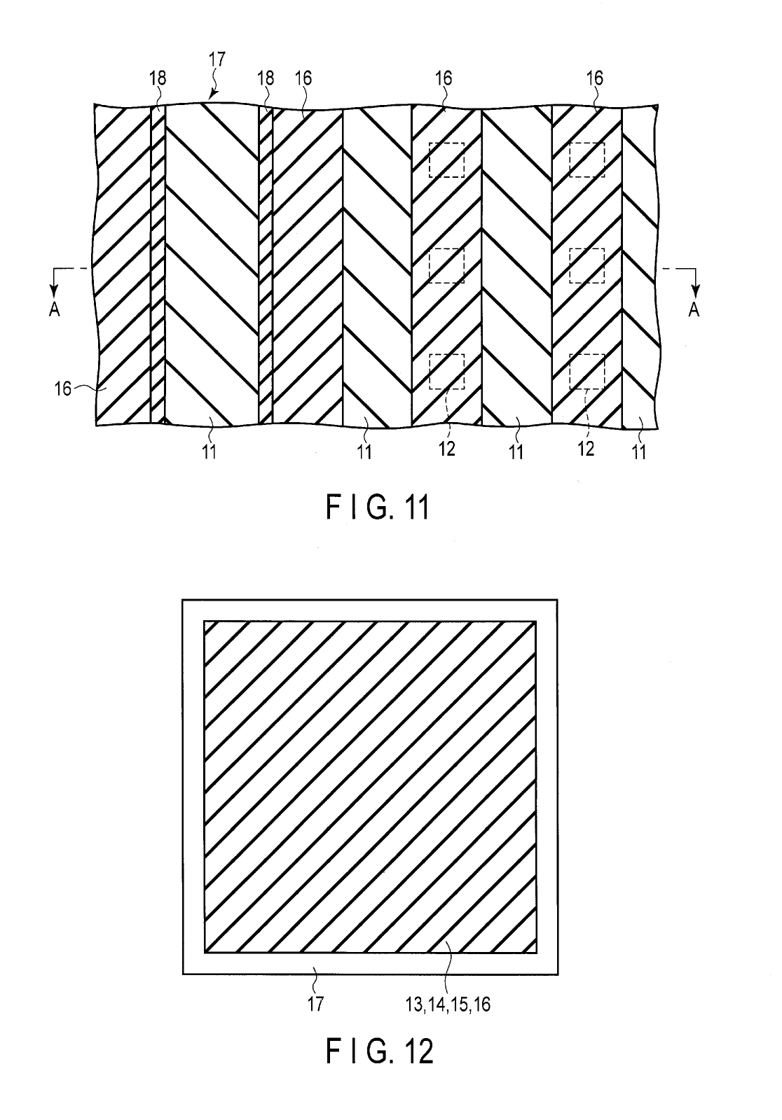

Next, as shown in FIGS. 3 and 10, predetermined processing is applied to the exposed portion of the catalytic layer 14 to form a compound layer 18 made of a compound of the main element contained in the catalytic layer 14. More specifically, gas processing, or wet processing using strong acid is applied as the predetermined processing. In this way, the catalytic metal compound layer 18 is selectively formed on the side surface of the catalytic layer 14. For example, an oxide, a nitride, a hydroxide or the like of the catalytic metal is formed. In the case of using nickel (Ni) as the catalytic metal, an NiO layer, an NiN layer or an Ni(OH)ₓ layer is formed on the side surface of the catalytic layer 14. The compound layer 18 has a function of protecting the catalytic layer 14 from dopant to be introduced into the graphene film 15 in the process which will be described later. That is, by forming the compound layer 18, it becomes possible to prevent the catalytic metal from being corroded or etched by dopant.

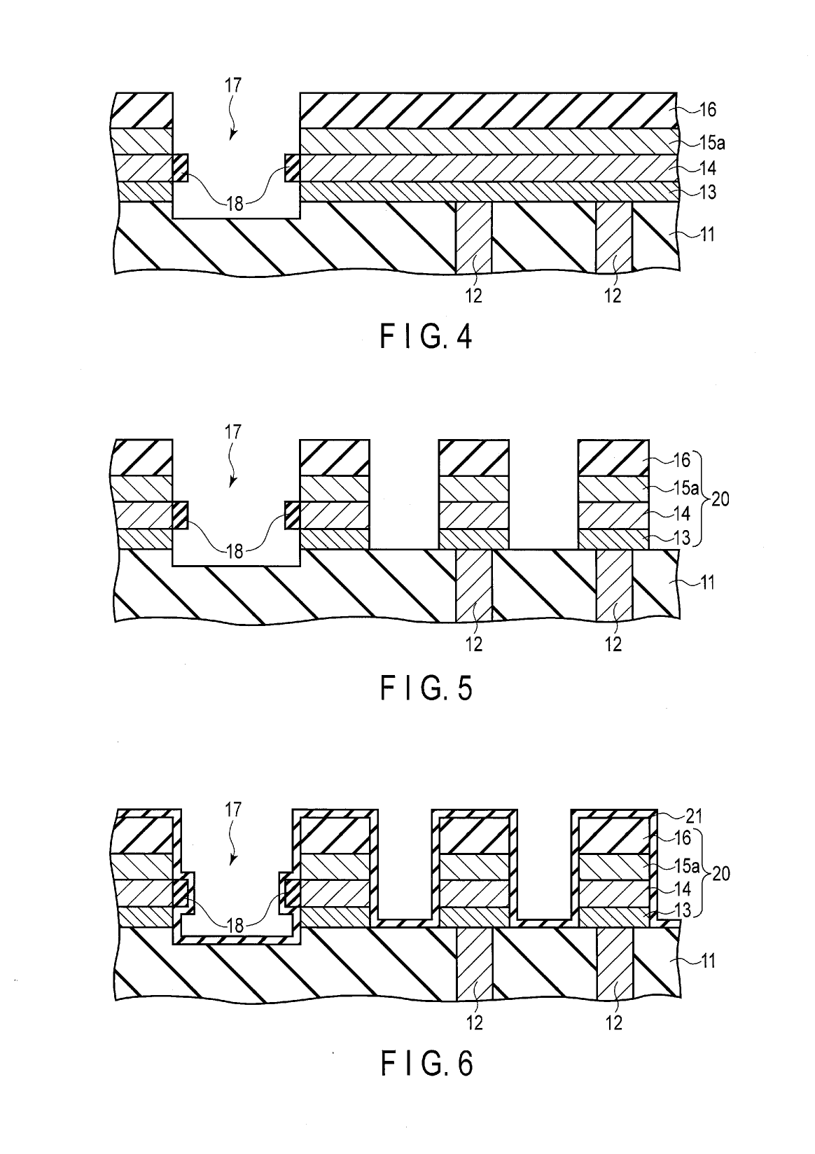

Next, as shown in FIG. 4, the dopant is introduced into the graphene film 15 from the side surface of the trench (step) 17. As a result, a graphene film 15a containing the dopant is obtained. The dopant contains a halogen element. More specifically, FeCl₃, CuCl₃, AlCl, AsF₅, Br or the like is used as the dopant. The dopant is introduced into the graphene film 15 by thermal diffusion. As described above, the graphene film 15 is formed of multilayer graphene of a plurality of stacked graphite layers. The dopant diffuses into the graphene film 15 through gaps between the graphite layers. Therefore, the dopant can be introduced even into a region of the graphene film 15 far from the side surface of the trench (step) 17. The introduced dopant is provided between the graphite layers of the multilayer graphene. In this way, the graphene film 15a containing the dopant and having low resistance can be obtained. Note that the region of the graphene film 15a containing the dophant preferably has a width of 1 μm or more to reduce the rate of the dopant escaping from the graphene film 15a.

In introducing the dopant into the graphene film 15, the catalytic layer 14 is protected from the dopant since the compound layer 18 is formed on the side surface of the catalytic layer 14. Therefore, even in the case of using halogen dopant having high reactivity, it is still possible to prevent the catalytic layer 14 from being corroded or etched by the dopant.

Next, as shown in FIGS. 5 and 11, the hard mask film 16 is patterned by photolithography or etching, and a hard mask pattern is formed. Subsequently, by using the hard mask pattern as a mask, the graphene film 15a containing the dopant, the catalytic layer 14 and the underlying conductive layer 13 are patterned. In this way, an interconnect structure 20 comprising the graphene interconnect 15a is formed.

Then, as shown in FIG. 6, a protective insulating film 21 which covers the interconnect structure 20 is formed. For the protective insulating film 21, a silicon nitride film, a silicon oxide film, a silicon oxynitride film or the like can be used. By forming the protective insulating film 21, it is possible to prevent the escape of the dopant from the graphene interconnect 15a.

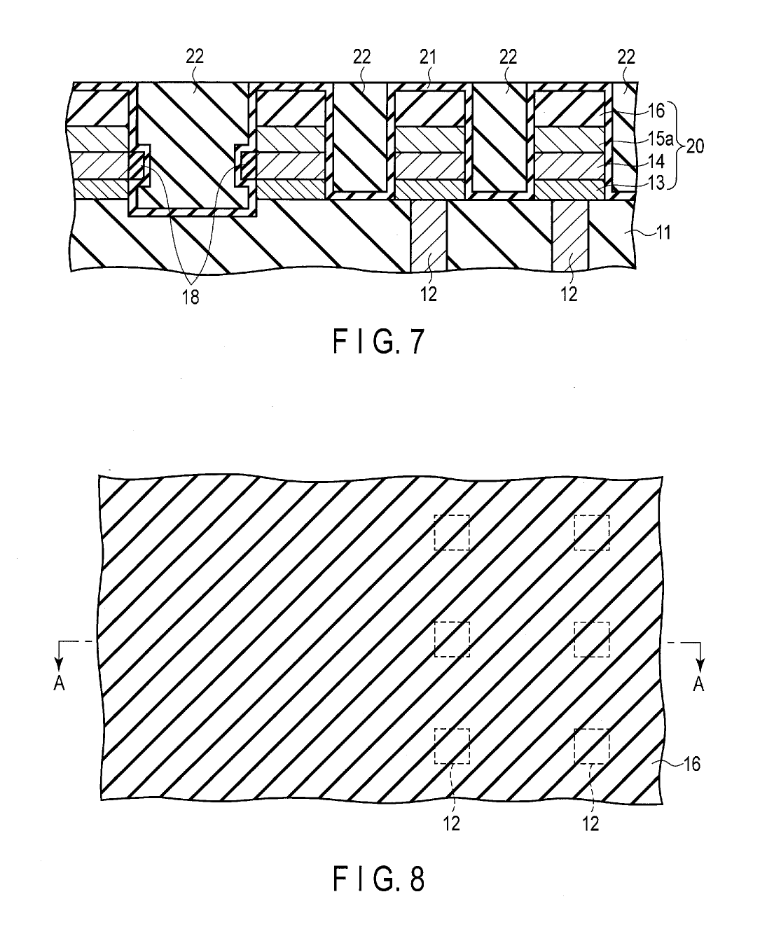

Subsequently, as shown in FIG. 7, an insulating film 22 is formed on the protective insulating film 21. In this way, the space between the interconnect structures 20 is filled with the insulating film 22. The insulating film 22 may be formed of a low-k film. Note that the region between the interconnect structures 20 may also be an air gap which is not filled with the insulating film 22.

As described above, according to the present embodiment, dopant is introduced into the graphene film 15 from the side surface of the trench (step) 17 formed in the graphene film 15 and the like, and then the graphene film 15a into which the dopant is introduced is patterned to form a graphene interconnect. If the dopant is introduced into the graphene film after the graphene film is patterned, most of the dopant escapes from the graphene film, and thus a graphene interconnect having low resistance cannot be obtained. In the present embodiment, since the dopant is introduced into the graphene film before the graphene film is patterned, most of the dopant remains in the graphene film without escaping therefrom. Therefore, it is possible in the present embodiment to prevent the escape of the dopant from the graphene film and to obtain a graphene interconnect having low resistance.

Further, the trench (step) 17 is formed in a region of the graphene film 15 not used as an interconnect. In the portion in which the trench (step) 17 is formed, the dopant may escape from the exposed side surface of the graphene film 15. However, there is no problem even if the dopant escapes from the exposed side surface because the portion in which the trench (step) 17 is formed is not used as an interconnect.

Still further, in the present embodiment, predetermined processing is applied to the exposed portion (side surface) of catalytic layer 14 to form the compound layer 18 made of a compound of the main element contained in the catalytic layer 14. The compound layer 18 is selectively formed on a predetermined surface of the catalytic layer 14 (side surface of the catalytic layer 14 in the present embodiment) which is not covered with the graphene film 15. Therefore, in introducing the dopant into the graphene film 15, the corrosion or the etching of the catalytic layer 14 by the dopant can be effectively prevented.

Next, modified examples of the present embodiment will be described.

FIG. 12 is an exemplary plan view of the manufacturing method of a first modified example of the present embodiment. In the present modified example, as shown in FIG. 12, a trench (step) 17 is formed in the periphery of the region in which the stacked film of an underlying conductive layer 13, a catalytic layer 14, a graphene film 15 and a hard mask film 16 is formed. That is, in the present modified example, the trench (step) 17 surrounds the portion of the graphene film 15 into which dopant is to be incorporated. With this structure, the dopant can be efficiently introduced into the graphene film 15.

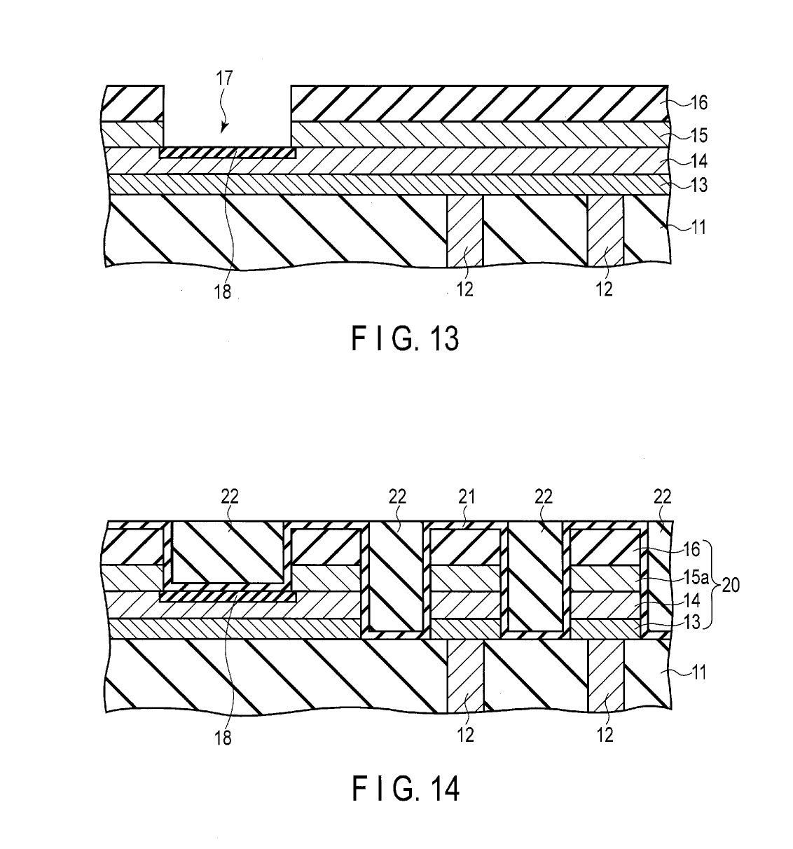

FIGS. 13 and 14 are exemplary sectional views of a part of the manufacturing method of a second modified example of the present embodiment.

As shown in FIG. 13, in the present modified example, a trench (step) 17 is formed by removing a hard mask film 16 and a graphene film 15. That is, in the present modified example, the upper surface of a catalytic layer 14 is exposed by removing the hard mask film 16 and the graphene film 15. In the present modified example, predetermined processing (similar to the processing of the above-described embodiment) is then applied to the exposed portion of the catalytic layer 14 (upper surface of the catalytic layer 14) to form a compound layer 18. Subsequently, the structure shown in FIG. 14 is obtained through processes similar to those of the first embodiment.

Also in the method of the present modified example, the corrosion or the etching of the catalytic layer 14 by the dopant can be prevented in a manner similar to that of the above-described embodiment.

Note that, in etching the graphene film 15 in the present modified example, the upper portion of the catalytic layer 14 is also etched to some extent. If the upper portion of the catalytic layer 14 is not etched, there is a possibility that the side surface of the graphene film 15 is partly covered with the compound layer 18. As a result, there is a possibility of decreasing the efficiency of introducing the dopant into the graphene film 15. By etching the upper portion of the catalytic layer 14, this problem can be prevented.

### Second Embodiment

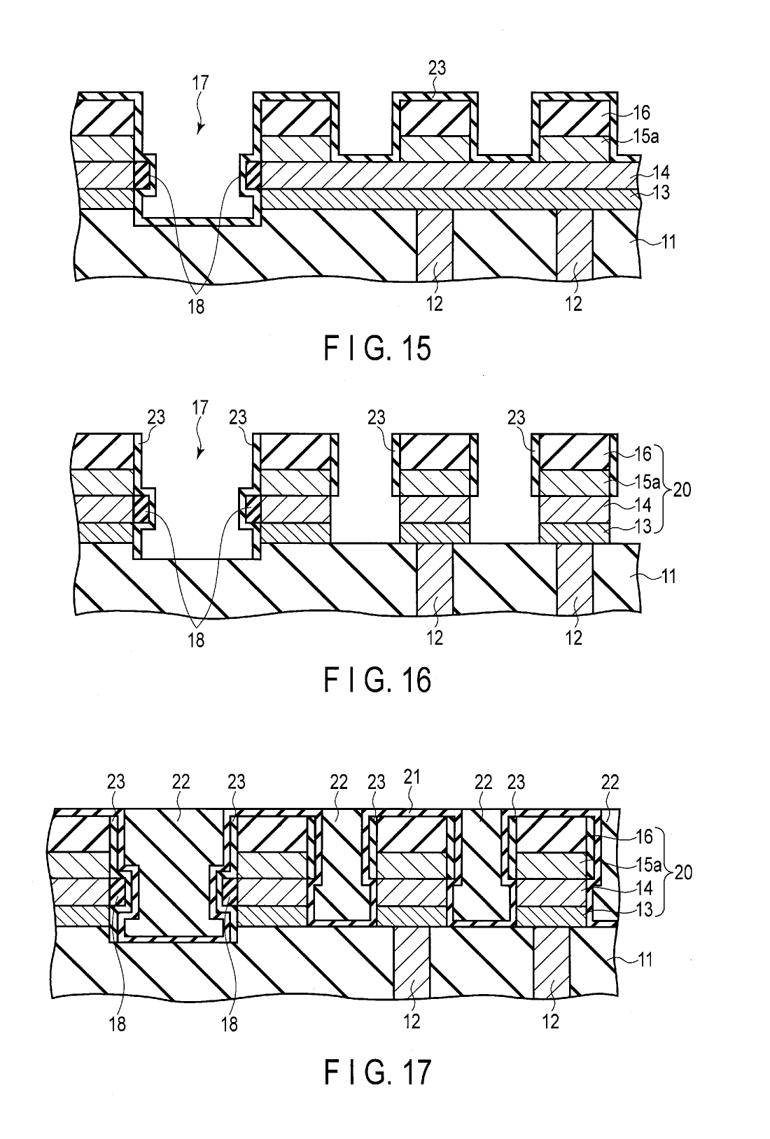

FIGS. 15 to 17 are exemplary sectional views of the method of manufacturing a semiconductor device of a second embodiment. Note that the basic structure and the basis manufacturing method are similar to those of the first embodiment and therefore the points described in the first embodiment are omitted.

First, through processes similar to those of FIGS. 1 to 4 of the first embodiment, a graphene film 15a containing dopant is obtained.

Next, as shown in FIG. 15, a hard mask film 16 is patterned. By using the hard mask film 16 as a mask, the graphene film 15a containing the dopant is then etched by oxygen plasma. In this way, a graphene interconnect 15a is formed. Here, the graphene film 15a into which the dopant is incorporated is patterned without patterning a catalytic layer 14.

Then, a first protective film 23 which covers the graphene interconnect 15a and the like is formed. For the first protective insulating film 23, a silicon nitride film, a silicon oxide film, a silicon oxynitride film or the like can be used. The first protective insulating film 23 is formed without exposing the graphene interconnect 15a to the air after the graphene interconnect 15a is formed by patterning the graphene film 15a into which the dopant is introduced. By forming the first protective insulating film 23 immediately after forming the graphene interconnect 15a in this way, the escape of the dopant from the graphene interconnect 15a can be effectively prevented. Further, since the dopant in the graphene interconnect 15a does not react with oxygen or water in the air, it is possible to retain the dopant in the graphene interconnect 15a more effectively.

Subsequently, as shown in FIG. 16, the catalytic layer 14 and the underlying conductive layer 13 are etched. In this way, an interconnect structure 20 comprising the graphene interconnect 15a is obtained.

Next, as shown in FIG. 17, a second protective insulating film 21 which covers the interconnect structure 20 and the first protective insulating film 23 is formed. Further, an insulating film 22 is formed on the second protective insulating film 21. In this way, the space between the interconnect structures 20 is filled with the insulating film 22. The second protective insulating film 21 and the insulating film 22 are similar to the protective insulating film 21 and the insulating film 22 of the first embodiment.

Also in the present embodiment, the basic structure and the basic manufacturing method are similar to those of the first embodiment, and therefore an effect similar to that produced by the first embodiment can be achieved.

Further, in the present embodiment, the side surface of the graphene interconnect 15a is covered with the first protective insulating film 23 as well as the second protective insulating film 21 which covers the first protective insulating film 23. The first protective insulating film 23 is provided on the side surface of the graphene interconnect 15a and is not provided on the side surface of the catalytic layer 14. Therefore, the portion of the protective insulating film provided on the side surface of the graphene interconnect 15a is thicker than the portion of the protective insulating film provided on the side surface of the catalytic layer 14. In the present embodiment, since the side surface of the graphene interconnect 15a is covered with a thick protective insulating film (protective insulating films 21 and 23), the escape of the dopant from the graphene interconnect 15a can be prevented effectively.

Still further, by using different insulating films for the first protective insulating film 23 and the second protective film 21, it is possible to realize a more effective protective function for the graphene interconnect 15a. For example, with the first protective insulating film 23 formed of a silicon nitride film, the oxidation of the graphene interconnect 15a can be prevented effectively. Further, with the second protective insulating film formed of a silicon oxide film, the escape of the dopant from the graphene interconnect 15a can be prevented effectively.

Note that, although the trench 17 is provided to introduce dopant into the graphene film in the above-described first and second embodiments, it is also possible to adopt any structure other than the trench 17 as long as the structure includes a step to expose the side surface of the graphene film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
forming a graphene film on a catalytic layer;
removing a part of the graphene film to form an exposed side surface of the graphene film;
introducing dopant into the graphene film from the exposed side surface; and
forming a graphene interconnect by patterning the graphene film into which the dopant is introduced.

2. The method of claim 1, wherein
the exposed side surface is formed in a region of the graphene film not used as the graphene interconnect.

3. The method of claim 1, wherein
a part of the catalytic layer is exposed by removing the part of the graphene film to form the exposed side surface of the graphene film; and
the method further comprising
forming a compound layer made of a compound of a main element contained in the catalytic layer by applying predetermined processing to the exposed part of the catalytic layer.

4. The method of claim 3, wherein
the exposed part of the catalytic layer corresponds to a side surface of the catalytic layer.

5. The method of claim 3, wherein
the exposed part of the catalytic layer corresponds to an upper surface of the catalytic layer.

6. The method of claim 1, further comprising
forming a protective insulating film which covers the graphene interconnect.

7. The method of claim 1, wherein
the graphene interconnect is formed by patterning the graphene film into which the dopant is introduced without patterning the catalytic layer; and
the method further comprising
forming a protective insulating film which covers the graphene interconnect formed without patterning the catalytic layer.

8. The method of claim 7, wherein
the protective insulating film is formed without exposing the graphene interconnect to the air, after forming the graphene interconnect by patterning the graphene film into which the dopant is introduced.

9. The method of claim 1, wherein
the exposed side surface constitutes a side surface of a trench.

10. The method of claim 1, wherein
the exposed side surface surrounds a part of the graphene film into which the dopant is introduced.

11. The method of claim 1, wherein
the dopant contains a halogen element.

12. The method of claim 1, wherein
the catalytic layer contains an element selected from cobalt (Co), nickel (Ni), iron (Fe), ruthenium (Ru) and copper (Cu).

13. A semiconductor device comprising:
a catalytic layer;
a graphene film provided on the catalytic layer and containing dopant; and
a compound layer which is provided on a predetermined surface of the catalytic layer not covered with the graphene film and is made of a compound of a main element contained in the catalytic layer.

14. The semiconductor device of claim 13, wherein
the predetermined surface corresponds to a side surface of the catalytic layer.

15. The semiconductor device of claim 13, wherein
the predetermined surface corresponds to an upper surface of the catalytic layer.

16. The semiconductor device of claim 13, wherein
the dopant contains a halogen element.

17. The semiconductor device of claim 13, wherein
the main element is selected from cobalt (Co), nickel (Ni), iron (Fe), ruthenium (Ru) and copper (Cu).

18. A semiconductor device comprising:
a catalytic layer;
a graphene interconnect provided on the catalytic layer and containing dopant; and
a protective insulating film provided on a side surface of the catalytic layer and a side surface of the graphene interconnect, wherein
a portion of the protective insulating film provided on the side surface of the graphene interconnect is thicker than a portion of the protective insulating film provided on the side surface of the catalytic layer.

19. The semiconductor device of claim 18, wherein
the protective insulating film includes a first protective insulating film and a second protective insulating film which covers the first protective insulating film, and
the first protective insulating film is provided on the side surface of the graphene interconnect and is not provided on the side surface of the catalytic layer.

20. The semiconductor device of claim 18, wherein
the dopant contains a halogen element.
